(19) United States
(12) Patent Application Publication
(10) Pub. No.: US 2025/0126921 A1
(43) Pub. Date: Apr. 17, 2025

(54) PHOTOELECTRIC CONVERSION APPARATUS AND PHOTOELECTRIC CONVERSION SYSTEM

(71) Applicant: CANON KABUSHIKI KAISHA, Tokyo (JP)

(72) Inventor: KAZUHIRO MORIMOTO, Kanagawa (JP)

(21) Appl. No.: 18/990,281

(22) Filed: Dec. 20, 2024

Related U.S. Application Data
(63) Continuation of application No. PCT/JP2023/020571, filed on Jun. 2, 2023.

(30) Foreign Application Priority Data
Jun. 29, 2022 (JP) 2022-104636

(51) Int. Cl. H10F 39/00; H01L 23/522

(52) U.S. Cl. CPC H10F 39/811; H01L 23/5228; H10F 39/809

(57) ABSTRACT

A photoelectric conversion apparatus including a first substrate including a first semiconductor layer and a first wiring structure stacked on the first semiconductor layer, and a second substrate including a second semiconductor layer and a second wiring structure stacked on the second semiconductor layer, includes an avalanche photodiode arranged on the first semiconductor layer, a first resistive element arranged on the first substrate and connected to the avalanche photodiode, a waveform shaping portion arranged on the second semiconductor layer and configured to shape an output signal of the avalanche photodiode, and a second resistive element arranged on the first substrate and connected to the avalanche photodiode, the waveform shaping portion, and the first resistive element.

### CROSS-REFERENCE TO RELATED APPLICATIONS

This application is a Continuation of International Patent Application No. PCT/JP2023/020571, filed Jun. 2, 2023, which claims the benefit of Japanese Patent Application No. 2022-104636, filed Jun. 29, 2022, both of which are hereby incorporated by reference herein in their entirety.

### BACKGROUND

### Technical Field

The present disclosure relates to a photoelectric conversion apparatus and a photoelectric conversion system using the photoelectric conversion apparatus.

### Background Art

As a method for enlarging the pixel area of a photoelectric conversion apparatus that uses an avalanche photodiode, a method in which a photoelectric conversion portion and a pixel circuit for processing signals from the photoelectric conversion portion are placed on different substrates and then the substrates are stacked is known.

### CITATION LIST

### Patent Literature

PTL 1: United States Patent Application Publication No. 2015/0115131

However, the configuration discussed in the specification of United States Patent Application Publication No. 2015/0115131 requires the use of a high-voltage transistor with a large element size in the pixel circuit when increasing a reverse bias that is applied to the avalanche photodiode. Therefore, there is an issue that it is difficult to achieve both high performance and miniaturization of pixels.

### SUMMARY

The present disclosure is directed to achieving both high performance and miniaturization of pixels.

According to an aspect of the present disclosure, a photoelectric conversion apparatus including a first substrate including a first semiconductor layer and a first wiring structure stacked on the first semiconductor layer, and a second substrate including a second semiconductor layer and a second wiring structure stacked on the second semiconductor layer, includes an avalanche photodiode arranged on the first semiconductor layer, a first resistive element arranged on the first substrate and connected to the avalanche photodiode, a waveform shaping portion arranged on the second semiconductor layer and configured to shape an output signal of the avalanche photodiode, and a second resistive element arranged on the first substrate and connected to the avalanche photodiode, the waveform shaping portion, and the first resistive element.

Further features of the present invention will become apparent from the following description of exemplary embodiments with reference to the attached drawings.

### BRIEF DESCRIPTION OF THE DRAWINGS

FIG. 1 is an outline diagram illustrating a photoelectric conversion apparatus according to an exemplary embodiment.

FIG. 2 is an outline diagram illustrating a sensor substrate of the photoelectric conversion apparatus according to the exemplary embodiment.

FIG. 3 is an outline diagram illustrating a circuit substrate of the photoelectric conversion apparatus according to the exemplary embodiment.

FIG. 4 illustrates an example of a configuration of a pixel circuit of the photoelectric conversion apparatus according to the exemplary embodiment,

FIG. 5A is a schematic diagram illustrating driving of the pixel circuit of the photoelectric conversion apparatus according to the exemplary embodiment.

FIG. 5B is a schematic diagram illustrating driving of the pixel circuit of the photoelectric conversion apparatus according to the exemplary embodiment.

FIG. 5C is a schematic diagram illustrating driving of the pixel circuit of the photoelectric conversion apparatus according to the exemplary embodiment.

FIG. 6 is a cross-sectional view illustrating a pixel portion of a photoelectric conversion apparatus according to a first exemplary embodiment.

FIG. 7A is a plan view illustrating the pixel portion of the photoelectric conversion apparatus according to the first exemplary embodiment.

FIG. 7B is a plan view illustrating the pixel portion of the photoelectric conversion apparatus according to the first exemplary embodiment.

FIG. 8A is a diagram illustrating an effect of the present invention.

FIG. 8B is a diagram illustrating an effect of the present invention.

FIG. 9 is a cross-sectional view illustrating a pixel portion of a photoelectric conversion apparatus according to a second exemplary embodiment.

FIG. 10A is a plan view illustrating the pixel portion of the photoelectric conversion apparatus according to the second exemplary embodiment.

FIG. 10B is a plan view illustrating the pixel portion of the photoelectric conversion apparatus according to the second exemplary embodiment.

FIG. 11 illustrates an example of a configuration of a pixel circuit of a photoelectric conversion apparatus according to a third exemplary embodiment.

FIG. 12 illustrates an example of a configuration of a pixel circuit of a photoelectric conversion apparatus according to a fourth exemplary embodiment.

FIG. 13 illustrates an example of a configuration of a pixel circuit of a photoelectric conversion apparatus according to a fifth exemplary embodiment.

FIG. 14 illustrates an example of a configuration of a pixel circuit of a photoelectric conversion apparatus according to a modified example of the fifth exemplary embodiment.

FIG. 15 is a functional block diagram illustrating a photoelectric conversion system according to a sixth exemplary embodiment.

FIG. 16A is a functional block diagram illustrating a photoelectric conversion system according to a seventh exemplary embodiment.

FIG. 16B is a functional block diagram illustrating a photoelectric conversion system according to a seventh exemplary embodiment.

FIG. 17 is a functional block diagram illustrating a photoelectric conversion system according to an eighth exemplary embodiment.

FIG. 18 is a functional block diagram illustrating a photoelectric conversion system according to a ninth exemplary embodiment.

FIG. 19A is a perspective view of glasses as an example of a photoelectric conversion system according to a tenth exemplary embodiment.

FIG. 19B is a perspective view of glasses as another example of a photoelectric conversion system according to a tenth exemplary embodiment.

### DESCRIPTION OF THE EMBODIMENTS

The forms described below are intended to embody the technical concept of the present invention but are not intended to limit the present invention. In the drawings, the sizes and positional relationships of components illustrated in the drawings are sometime exaggerated for clarity. In the following descriptions, corresponding configurations are assigned the same reference numerals, and redundant descriptions thereof are sometimes omitted.

Exemplary embodiments of the present invention will be described in detail below with reference to the drawings. In the following descriptions, terms indicating specific directions or positions (e.g., “upper”, “lower”, “right”, “left”, and other terms including the foregoing terms) are used where necessary. The terms are used to facilitate understanding of the exemplary embodiments with reference to the drawings, and the technical scope of the present invention should not be limited by the definitions of the terms.

In the present specification, a plan view refers to viewing from a direction perpendicular to a light incident surface of a semiconductor layer. Further, a cross-sectional view refers to a surface along a plane that is perpendicular to the light incident surface of the semiconductor layer. In cases where the light incident surface of the semiconductor layer is a rough surface when viewed microscopically, the plan view is defined based on the light incident surface of the semiconductor layer as viewed macroscopically.

In the following descriptions, the anodes of avalanche photodiodes (APDs) are fixed at constant potentials, and signals are extracted from the cathode side. Therefore, a first conductivity type semiconductor region where the majority carriers are charges with the same polarity as the signal charge is an N-type semiconductor region, whereas a second conductivity type semiconductor region where the majority carriers are charges with a different polarity than the signal charge is a P-type semiconductor region. The present invention still applies even in cases where the cathodes of the APDs are fixed at constant potentials and signals are extracted from the anode side. In such cases, the first conductivity type semiconductor region where the majority carriers are charges with the same polarity as the signal charge is a P-type semiconductor region, whereas the second conductivity type semiconductor region where the majority carriers are charges with a different polarity than the signal charge is an N-type semiconductor region. A case where one of the nodes of each APD is fixed at a constant potential will be described below. However, the potentials of both nodes may vary.

In the present specification, the term “impurity concentration” used alone refers to the net impurity concentration obtained by subtracting the compensation provided by impurities of the opposite conductivity type. Specifically, the term “impurity concentration” refers to an NET doping concentration. A region where the P-type dopant concentration is higher than the N-type dopant concentration refers to a P-type semiconductor region. On the other hand, a region where the N-type dopant concentration is higher than the P-type dopant concentration refers to an N-type semiconductor region.

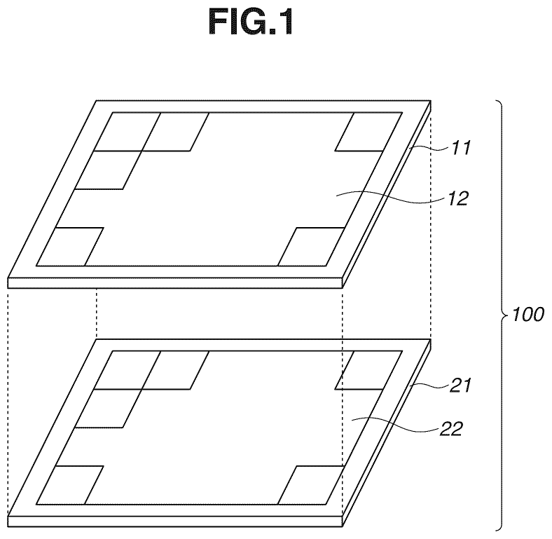

Common configurations of a processing apparatus, a photoelectric conversion apparatus designed for use with the processing apparatus, and a driving method thereof according to exemplary embodiments of the present invention will be described below with reference to FIGS. 1 to 5C. While the processing apparatus provided outside the photoelectric conversion apparatus will be described below, the processing apparatus may be configured, for example, inside the photoelectric conversion apparatus.

FIG. 1 is a diagram illustrating a configuration of a stacked-type photoelectric conversion apparatus 100 according to an exemplary embodiment of the present invention. The photoelectric conversion apparatus 100 is composed of two substrates that are a sensor substrate 11 and a circuit substrate 21 stacked on top of one another and electrically connected to each other. The sensor substrate 11 is a first substrate, and the circuit substrate 21 is a second substrate. The sensor substrate 11 includes a first semiconductor layer and a first wiring structure. The first semiconductor layer includes photoelectric conversion elements 102 described below. The circuit substrate 21 includes a second semiconductor layer and a second wiring structure. The second semiconductor layer includes circuits such as signal processing units 103 described below. The photoelectric conversion apparatus 100 is composed of the second semiconductor layer, the second wiring structure, the first wiring structure, and the first semiconductor layer stacked in this order. The photoelectric conversion apparatus according to each exemplary embodiment is a rear-illuminated photoelectric conversion apparatus with a first surface from which light is incident and a second surface where a circuit substrate is provided.

While the sensor substrate 11 and the circuit substrate 21 that are diced chips will be described below, the sensor substrate 11 and the circuit substrate 21 are not limited to chips. For example, each substrate may be a wafer. Further, each substrate in the form of a wafer may be stacked and then diced, or each substrate may be formed into a chip, and then the chips may be stacked and bonded together.

A pixel region 12 is arranged on the sensor substrate 11, and a circuit region 22 is arranged on the circuit substrate 21. The circuit region 22 processes signals detected by the pixel region 12.

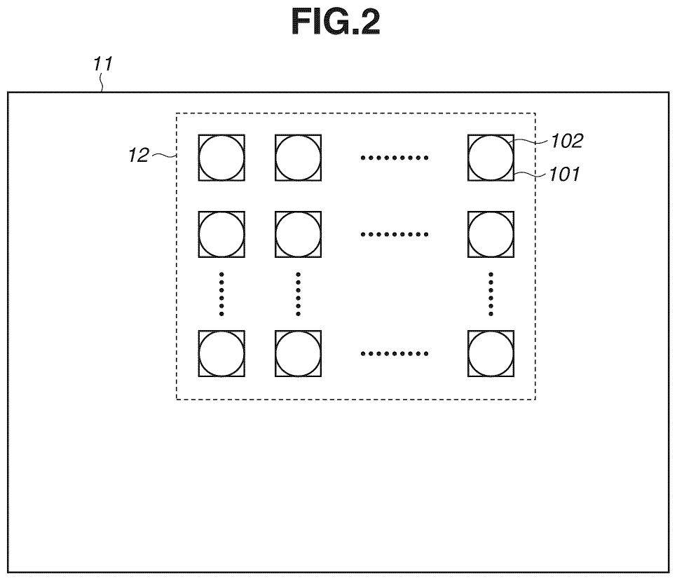

FIG. 2 is a diagram illustrating an example of an arrangement on the sensor substrate 11. Pixels 101 including the photoelectric conversion elements 102 with APDs are arranged in a two-dimensional array in a plan view, whereby the pixel region 12 is formed.

The pixels 101 are typically pixels for generating images. However, in cases where the pixels 101 are used for Time of Flight (TOF), the pixels 101 do not necessarily have to generate images. Specifically, the pixels 101 may be pixels for measuring the time of arrival and intensity of light.

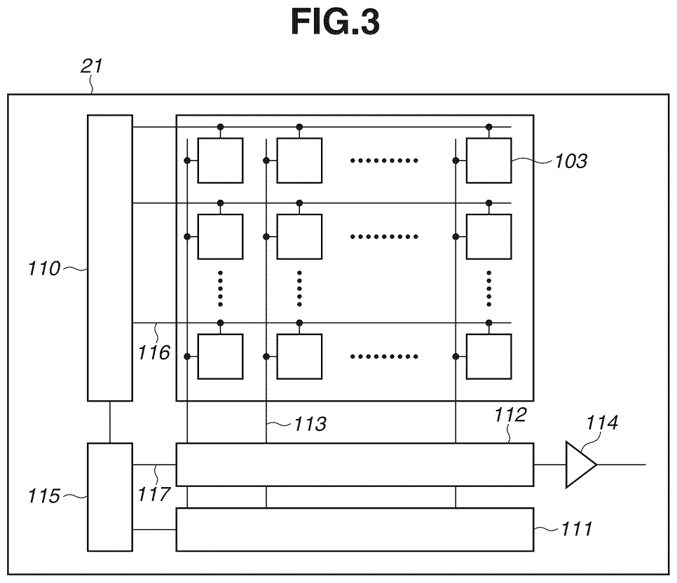

FIG. 3 is a diagram illustrating a configuration of the circuit substrate 21. The signal processing units 103, a reading circuit (column circuit) 112, a control pulse generation unit 115, a horizontal scanning circuit portion 111, signal lines 113, and a vertical scanning circuit portion 110 are included. The signal processing units 103 process charges photoelectrically converted by the photoelectric conversion elements 102 illustrated in FIG. 2.

The photoelectric conversion elements 102 in FIG. 2 and the signal processing units 103 in FIG. 3 are electrically connected through connection traces provided for each pixel 101.

The vertical scanning circuit portion 110 receives control pulses supplied from the control pulse generation unit 115 and supplies control pulses to each pixel. Logic circuits such as shift registers and address decoders are used in the vertical scanning circuit portion 110.

Signals output from the photoelectric conversion elements 102 of the pixels are processed by the signal processing units 103. The signal processing units 103 are provided with counters and memories, and digital values are held in the memories.

The horizontal scanning circuit portion 111 inputs control pulses for sequentially selecting each column to the signal processing units 103 in order to read signals from the memories of each pixel in which the digital signals are held.

Signals are output to the signal lines 113 from the signal processing units 103 of the pixels selected by the vertical scanning circuit portion 110 for each selected column.

The signals output to the signal lines 113 are output via an output circuit 114 to an external recording unit or an external signal processing unit located outside the photoelectric conversion apparatus 100.

In FIG. 2, the photoelectric conversion elements in the pixel region may be arranged one-dimensionally. The function of the signal processing unit does not necessarily have to be provided for each photoelectric conversion element individually. For example, one signal processing unit may be shared by a plurality of photoelectric conversion elements and may sequentially perform signal processing.

As illustrated in FIGS. 2 and 3, the plurality of signal processing units 103 is arranged in a region that overlaps with the pixel region 12 in a plan view. Further, the vertical scanning circuit portion 110, the horizontal scanning circuit portion 111, column circuit 112, the output circuit 114, and the control pulse generation unit 115 are arranged to overlap with a region between an edge of the sensor substrate 11 and an edge of the pixel region 12 in a plan view. In other words, the sensor substrate 11 includes the pixel region 12 and a non-pixel region around the pixel region 12, and the vertical scanning circuit portion 110, the horizontal scanning circuit portion 111, column circuit 112, the output circuit 114, and the control pulse generation unit 115 are arranged in a region that overlaps with the non-pixel region in a plan view.

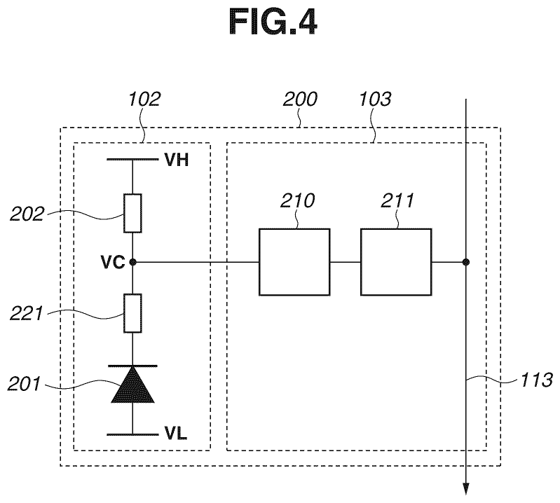

FIG. 4 illustrates an example of a block diagram including equivalent circuits of FIGS. 2 and 3.

In FIG. 4, the photoelectric conversion element 102 including an avalanche photodiode (APD) 201 is provided on the sensor substrate 11, and the other components are provided on the circuit substrate 21.

The APD 201 is a photoelectric conversion portion that generates a pair of charges corresponding to incident light by photoelectric conversion. A voltage VL (first voltage) is supplied to an anode of the APD 201. Further, a voltage VH (second voltage) higher than the voltage VL supplied to the anode of the APD 201 is supplied to a cathode of the APD 201. A reverse bias voltage for causing the APD 201 to perform avalanche multiplication operation is supplied to the anode and the cathode. With the supplied voltage, the charges generated by the incident light cause avalanche multiplication, resulting in an avalanche current. Two power supply wiring systems for supplying voltage to the cathode and the anode of the APD 201 individually are arranged on the first substrate.

In the cases where the reverse bias voltage is supplied, the potential difference between the anode and the cathode is operated at a potential difference that exceeds a breakdown voltage in a Geiger mode, while the potential difference between the anode and the cathode is operated at a potential difference that is close to, equal to, or below the breakdown voltage in a linear mode.

The APD that is operated in the Geiger mode is referred to as a single-photon avalanche diode (SPAD). For example, the voltage VL (first voltage) is −30 V, and the voltage VH (second voltage) is 1 V. The APD 201 may be operated in the linear mode or in the Geiger mode. SPADs are preferred because their potential difference is greater than that of an APD in the linear mode, which significantly improves the signal-to-noise ratio.

A first resistive element 202 is connected between a power supply that supplies the voltage VH and the APD 201. The first resistive element 202 functions as a load circuit (quenching circuit) during signal multiplication by avalanche multiplication and has a function (quenching operation) of suppressing the avalanche multiplication by reducing the voltage supplied to the APD 201. Further, the first resistive element 202 also has a function (recharging operation) of returning the voltage supplied to the APD 201 to the voltage VH by passing a current corresponding to a voltage drop caused by the quenching operation.

A second resistive element 221 is provided between the first resistive element 202 and the APD 201. The provision of the second resistive element 221 is a feature of the present invention, and functions thereof will be described below.

Each of the signal processing units 103 includes a waveform shaping portion 210 and a counter circuit 211. In the present specification, it is sufficient for the signal processing unit 103 to include either one of the waveform shaping portion 210 and the counter circuit 211.

The waveform shaping portion 210 shapes a potential change of the cathode of the APD 201 that occurs when a photon is detected and outputs a pulse signal. For example, an inverter circuit is used as the waveform shaping portion 210. It is also possible to use a circuit with a plurality of inverters connected in series or another circuit that has a waveform shaping effect.

The counter circuit 211 counts the pulse signals output from the waveform shaping portion 210 and holds the count value.

A switch, such as a transistor, may be provided between the first resistive element 202 and the APD 201 or between the photoelectric conversion element 102 and the signal processing unit 103 to switch the electrical connection. Similarly, the supply of the voltage VH or the voltage VL to the photoelectric conversion element 102 may be switched electrically using a switch, such as a transistor.

The present exemplary embodiment describes the configuration that uses the counter circuit 211. However, the photoelectric conversion apparatus 100 may acquire pulse detection timings using a time-to-digital conversion (hereinafter, TDC) circuit and a memory instead of the counter circuit 211. In this case, generation timings of pulse signals output from the waveform shaping portion 210 are converted into digital signals by the TDC. For the pulse signal timing measurement, a control pulse pREF (reference signal) is supplied to the TDC from the vertical scanning circuit portion 110 in FIG. 1 via a drive line. The TDC acquires a signal as a digital signal when an input timing of a signal output from each pixel via the waveform shaping portion 210 is set as a relative time using the control pulse pREF as a reference,

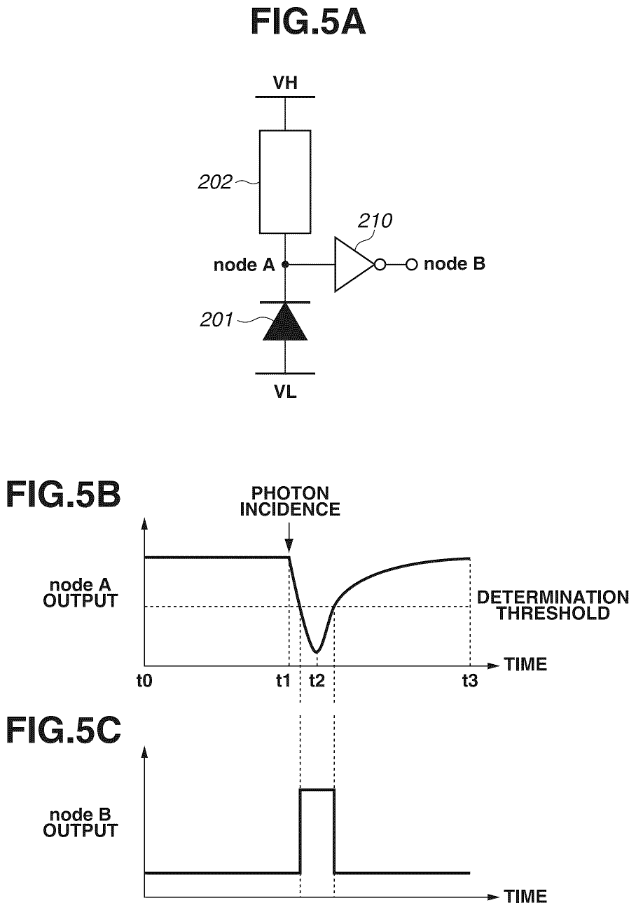

FIGS. 5A and 5B are diagrams schematically illustrating relationships between the APD operation and output signals.

FIG. 5A is a diagram illustrating the APD 201, the first resistive element 202, and the waveform shaping portion 210 extracted from FIG. 4. In FIG. 5A, nodes A and B respectively indicate the input and output sides of the waveform shaping portion 210. FIG. 5B illustrates waveform changes of the node A illustrated in FIG. 5A, and FIG. 5C illustrates waveform changes of the node B illustrated in FIG. 5A.

From time t0 to time t1, a potential difference VH-VL is applied to the APD 201 illustrated in FIG. 5A. At time t1 when a photon is incident on the APD 201, avalanche multiplication occurs in the APD 201, and an avalanche multiplication current flows into the first resistive element 202, resulting in a voltage drop at the node A. In a case where the amount of voltage drop further increases and the potential difference applied to the APD 201 decreases, the avalanche multiplication in the APD 201 stops at time t2, and the voltage level of the node A no longer drops below a certain value.

Thereafter, from time t2 to time t3, a current that compensates for the voltage drop flows into the node A from the voltage VL, and at time t3, the node A stabilizes at the original potential level. At this time, a portion of the output waveform at the node A that exceeds a threshold is shaped by the waveform shaping portion 210, and the resulting waveform is output as a signal from the node B.

The arrangement of the signal lines 113 and the arrangement of the column circuit 112 and the output circuit 114 are not limited to those illustrated in FIG. 3. For example, the signal lines 113 may be arranged to extend in the row direction, and the column circuit 112 may be arranged at the end of the signal lines 113.

Photoelectric conversion apparatuses according to various exemplary embodiments will be described below.

### FIRST EXEMPLARY EMBODIMENT

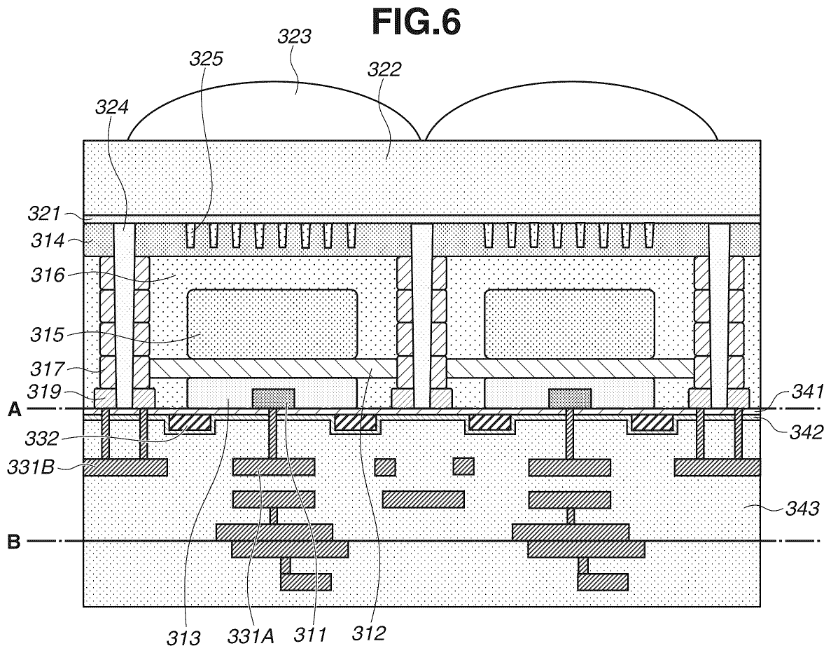

A photoelectric conversion apparatus according to a first exemplary embodiment will be described below with reference to FIGS. 6 to 8B.

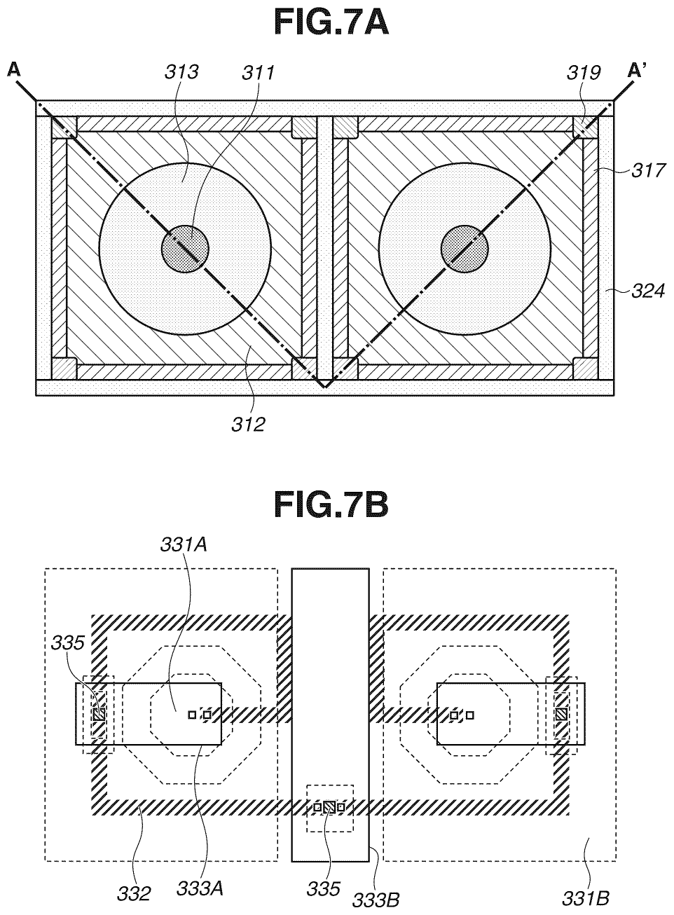

FIG. 6 is a cross-sectional view illustrating the photoelectric conversion elements 102 of two pixels of the photoelectric conversion apparatus according to the first exemplary embodiment, along a direction perpendicular to a substrate surface direction. The cross-sectional view corresponds to a cross section along A-A′ specified in FIG. 7A. A structure and function of the photoelectric conversion elements 102 will be

described below. Each photoelectric conversion element 102 includes an N-type first semiconductor region 311, a third semiconductor region 313, a fifth semiconductor region 315, and a sixth semiconductor region 316. Each photoelectric conversion element 102 further includes a P-type second semiconductor region 312, a fourth semiconductor region 314, a seventh semiconductor region 317, and a ninth semiconductor region 319.

According to the present exemplary embodiment, in the cross section illustrated in FIG. 6, the N-type first semiconductor region 311 is formed in the vicinity of a surface on the opposite side to the light incident surface, and the N-type third semiconductor region 313 is formed around the N-type first semiconductor region 311. The P-type second semiconductor region 312 is formed at a position that overlaps with the first and second semiconductor regions in a plan view. The N-type fifth semiconductor region 315 is arranged at a position that overlaps with the second semiconductor region 312 in a plan view, and the N-type sixth semiconductor region 316 is formed around the N-type fifth semiconductor region 315.

The first semiconductor region 311 is higher in N-type impurity concentration than the third semiconductor region 313 and the fifth semiconductor region 315. A PN junction is formed between the P-type second semiconductor region 312 and the N-type first semiconductor region 311. By setting the impurity concentration of the second semiconductor region 312 lower than the impurity concentration of the first semiconductor region 311, an entire region of the second semiconductor region 312 that overlaps with the center of the first semiconductor region in a plan view becomes a depletion layer region. In this case, the potential difference between the first semiconductor region 311 and the second semiconductor region 312 becomes greater than the potential difference between the second semiconductor region 312 and the fifth semiconductor region 315. Furthermore, the depletion layer region extends to a portion of the first semiconductor region 311, and a strong electric field is induced in the extended depletion layer region. This strong electric field causes avalanche multiplication in the depletion layer region extended to the portion of the first semiconductor region 311, and a current based on the amplified charge is output as a signal charge. When light incident on the photoelectric conversion elements 102 is photoelectrically converted and avalanche multiplication occurs in the depletion layer region (avalanche multiplication region), the generated first conductivity type charge is collected in the first semiconductor region 311.

While the third semiconductor region 313 and the fifth semiconductor region 315 in FIG. 6 are formed to have similar sizes, the sizes of the semiconductor regions are not limited to those in FIG. 6. For example, the fifth semiconductor region 315 may be formed larger than the third semiconductor region 313, and charges from a wider area may be collected in the first semiconductor region 311.

Further, the third semiconductor region 313 may be a P-type semiconductor region instead of an N-type semiconductor region. In this case, the impurity concentration of the third semiconductor region 313 is set lower than the impurity concentration of the second semiconductor region 312, because in a case where the impurity concentration of the third semiconductor region 313 is excessively high, the region between the third semiconductor region 313 and the first semiconductor region 311 becomes an avalanche multiplication region, which increases a dark count rate (DCR).

Uneven structures 325 are formed by trenches in a semiconductor layer surface on the light incident surface side. The uneven structures 325 are surrounded by the P-type fourth semiconductor region 314 and scatter the light that is incident on the photoelectric conversion element 102. Since the incident light travels diagonally in the photoelectric conversion element 102, an optical path length that is greater than or equal to the thickness of a semiconductor layer 301 is achieved, which makes it possible to photoelectrically convert light with longer wavelengths compared to cases without the uneven structures 325. Further, since the uneven structures 325 prevent reflection of the incident light in the substrate, an effect of enhancing the photoelectric conversion efficiency of the incident light is achieved. Furthermore, light diffracted in a diagonal direction by the uneven structures 325 is efficiently reflected by a wiring portion arranged in the vicinity of the surface on the opposite side to the light incident surface, which further enhances near-infrared sensitivity.

The fifth semiconductor region 315 and the uneven structures 325 are formed to overlap in a plan view. The area of the overlap of the fifth semiconductor region 315 and the uneven structures 325 in a plan view is greater than the area of the portion of the fifth semiconductor region 315 that does not overlap with the uneven structures 325. Charges generated far from an avalanche multiplication region formed between the first semiconductor region 311 and the fifth semiconductor region 315 require a longer time to reach the avalanche multiplication region compared to charges generated near the avalanche multiplication region. Thus, there is a possibility of an increase in timing jitter. By arranging the fifth semiconductor region 315 and the uneven structures 325 to overlap in a plan view, an electric field in a deep region of the photodiode is enhanced, which reduces the time required to collect charges generated far from the avalanche multiplication region, making it possible to decrease timing jitter.

Further, since the fourth semiconductor region 314 covers the uneven structures 325 three-dimensionally, generation of thermally excited charges at interfaces of the uneven structures 325 is suppressed. This reduces the DCR of the photoelectric conversion element.

Each pixel is isolated by a pixel isolation portion 324 with a trench structure, and the P-type seventh semiconductor region 317 formed around the pixel isolation portion 324 isolates the adjacent photoelectric conversion elements with a potential barrier. Since the photoelectric conversion elements are isolated also by the potential of the seventh semiconductor region 317, the trench structure of the pixel isolation portion 324 is not mandatory, and even in a case where the pixel isolation portion 324 with the trench structure is provided, the depth and position thereof are not limited to those in FIG. 6. The pixel isolation portion 324 may be a deep trench isolation (DTI) extending through the semiconductor layer or a DTI that does not extend through the semiconductor layer. A metal may be embedded in the DTI to enhance light-shielding performance. The pixel isolation portion 324 may be composed of SiO, fixed charge film, metal member, polysilicon, or a combination thereof. The pixel isolation portion 324 may be configured to surround the entire circumference of the photoelectric conversion element in a plan view or may be configured, for example, only on opposite side portions of the photoelectric conversion element. A voltage may be applied to an embedded member to induce charges at trench interfaces to decrease the DCR.

A distance from the pixel isolation portion to the adjacent pixel or the pixel arranged at the nearest position can be considered the size of one photoelectric conversion element 102. A distance d from the light incident surface to the avalanche multiplication region satisfies L √2/4<d<L×√2, where L is the size of one photoelectric conversion element 102. In a case where the size and depth of the photoelectric conversion element satisfy the foregoing inequality, the strength of the electric field in the depth direction is comparable to that of the electric field in the planar direction in the vicinity of the first semiconductor region 311. Since the variation in the time required for charge collection is suppressed, it becomes possible to reduce and improve timing jitter.

A pinning film 321, a flattening film 322, and microlenses 323 are further arranged on the light incident surface side of the semiconductor layer. A filter layer (not illustrated) may also be arranged on the light incident surface side. Various optical filters, such as a color filter, an infrared cut filter, and a monochrome filter, can be used in the filter layer. A red-green-blue (RGB) color filter or a red-green-blue-white (RGBW) color filter can be used in the color filter.

A wiring structure including a conductor and an insulating film is provided on the surface on the opposite side to the light incident surface of the semiconductor layer. The photoelectric conversion elements 102 illustrated in FIG. 6 include an oxide film 341 and a protective film 342 in this order from the side close to the semiconductor layer, and a wiring layer made of a conductor is further layered. A film 343 between wiring layers is an insulating film provided between traces and semiconductor layers and between wiring layers. The protective film 342 is a film for protecting the APDs from plasma damage and metal contamination during etching. SiN, which is a nitride film, is commonly used, but it is also possible to use SiON, SiC, or SiCN.

A cathode trace 331A is connected to the first semiconductor region 311, and an anode trace 331B supplies a voltage to the seventh semiconductor region 317 via the ninth semiconductor region 319, which is an anode contact. According to the present exemplary embodiment, the cathode trace 331A and the anode trace 331B are arranged in the same wiring layer. The wiring portion is made of a conductor that uses a metal, such as Cu or Al, as a main material. A resistive element 332 is connected to the cathode trace 331A and functions as a quench resistor. Materials that can be used for the resistive element 332 include silicon-based materials such as polysilicon and amorphous silicon, transparent electrodes made of inorganic materials, metal thin-film materials such as NiCr, ceramic materials such as TIN, TaN, TaSi, and WN, and organic materials. Preferably, the materials used in the resistive element 332 have higher resistivity than the main materials used in the cathode trace 331A and the anode trace 331B.

FIGS. 7A and 7B are plan views illustrating two pixels of the photoelectric conversion apparatus according to the first exemplary embodiment. FIG. 7A is a plan view illustrating the semiconductor regions as viewed from the surface on the opposite side to the light incident surface, and FIG. 7B is a plan view illustrating the wiring portion as viewed from the surface on the opposite side to the light incident surface.

In FIG. 7A, the first semiconductor region 311, the third semiconductor region 313, and the fifth semiconductor region 315 are circular and arranged concentrically. This structure suppresses local electric field concentration at an edge portion of a strong electric field region between the first semiconductor region 311 and the second semiconductor region 312, which makes it possible to achieve an effect of reducing the DCR. The shapes of the semiconductor regions are not limited to circular shapes and may be, for example, polygons with aligned centroid positions.

In FIG. 7B, the resistive element 332 is formed by a fine line pattern and is electrically connected to the cathode trace 331A and a power supply trace 333B via contact plugs and wiring layers. Contact plugs 335 are formed above middle portions of the resistive element 332 and are electrically connected to a wiring portion 333A. The wiring portion 333A is electrically connected to the signal processing unit 103 arranged on the circuit substrate 21 via the connection trace provided for each pixel. According to the present exemplary embodiment, one resistive element 332 continuously forms elements corresponding to the first resistive element 202 and the second resistive element 221 illustrated in FIG. 4, which facilitates a reduction of the layout area. However, the two resistive elements may be arranged by physically separating the two resistive elements. For example, the resistive elements 202 and 221 may be provided in separate wiring layers and may be electrically connected to each other via a member made of a main material different from the main materials of the resistive elements 202 and 221.

Further, the resistive element 332 needs to have a resistance value set sufficiently high to quench the multiplication current of the APD, and a resistance of 10 kOhm or more is required. Preferably, the resistance value of the resistive element 332 is, for example, 50 kOhm or more but can be 30 kOhm or more. Meanwhile, considering the time required to recover from a potential change associated with avalanche multiplication, a resistance value of 1 MOhm or less is preferred. In order to achieve a high resistance value in a limited pixel area, a sufficiently small cross-sectional area of the resistive element 332 is preferred. For example, it is preferable to set the thickness to 1/10 or less of the width of the resistive element 332. In other words, a ratio of a shortest side to a longest side of the resistive element 332 in a cross section is preferably 10 or higher.

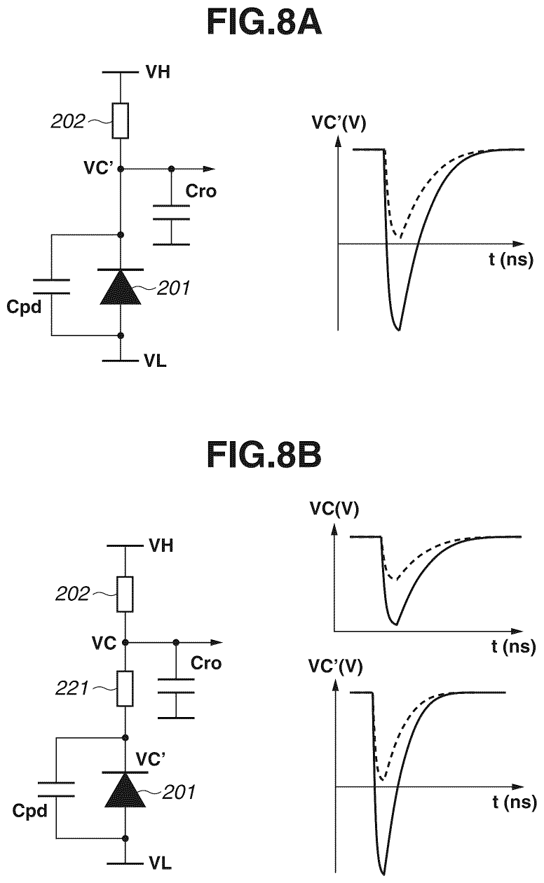

Effects of the present exemplary embodiment compared to conventional configurations will be described below with reference to FIGS. 8A and 8B. FIG. 8A illustrates an example of a configuration and operation of a conventional quenching circuit. The APD 201 is connected in series to the first resistive element 202, and a photodiode capacitance Cpd and another parasitic capacitance Cro including a wiring capacitance and a gate capacitance of the reading circuit 112 are added as parasitic capacitance components to the cathode terminal.

FIG. 8A is a graph illustrating temporal changes in cathode potential VC′ when a photon is detected by the APD 201. A dashed line corresponds to a case where an excess bias Vex is low, and a solid line corresponds to a case where the excess bias Vex is high. In general, increasing the excess bias Vex applied to the APD enhances the photon detection efficiency and reduces timing jitter. Meanwhile, VC′ becomes approximately equal in signal amplitude to Vex, so that as Vex is increased, the output waveform amplitude of VC′ increases, and a transistor connected subsequently may cause gate breakdown. Using a thick oxide film transistor with high voltage resistance to avoid gate breakdown leads to an increased footprint of the pixel circuit, which makes integration difficult. Therefore, it can be said that there is a trade-off between pixel performance, such as photon detection efficiency and timing jitter, and pixel integration. For example, in cases where Vex that corresponds to the waveform indicated with the solid line is applied, it is difficult to miniaturize the pixel circuit, so that in the case of miniaturizing the pixel circuit, it is only possible to apply up to Vex that corresponds to the waveform indicated with the dashed line. In a quenching circuit configuration of the present invention illustrated in FIG. 8B, the first resistive element 202 and the second resistive element 221 are connected in series to the APD 201. In this case, Cpd is the only parasitic capacitance component that is directly added to the cathode terminal, and Cro is added via the second resistive element 221. As in FIG. 8A, the cathode potential VC′ becomes approximately equal in signal amplitude to Vex. Meanwhile, the signal amplitude of the terminal connected to the subsequent circuit at the potential VC becomes smaller than Vex due to a voltage divider effect caused by the series resistance and a low-pass filter effect of the second resistive element 221 and the parasitic capacitance Cro. Especially, by setting the second resistive element 221 to a resistance value that is greater than or equal to the resistance value of the first resistive element 202, the voltage divider effect is enhanced, which makes it possible to suppress the occurrence of dielectric breakdown without using a thick oxide film transistor with high voltage resistance in the pixel circuit. Specifically, the resistance value of the second resistive element 221 is set to be greater than or equal to the resistance value of the first resistive element 202. A voltage divider ratio that reduces the signal amplitude to approximately 0.9 times to 0.01 times is more preferred and, for example, the resistance values of the resistive elements 202 and 221 can be set to approximately 10 kOhm and 40 kOhm, respectively. This facilitates area reduction of the pixel circuit even in cases where Vex is increased, making it possible to achieve both high performance and miniaturization of pixels.

The first resistive element 202 connected to a first avalanche photodiode of the left one of the two pixels in FIGS. 6, 7A, and 7B and the first resistive element 202 connected to a second avalanche photodiode of the right one of the two pixels are provided at the same height in the wiring structure. In other words, the first resistive elements 202 are formed on the same plane parallel to the surface of the first semiconductor layer. It can also be said that the first resistive elements 202 are provided in the same wiring layer in the wiring structure.

Another resistive element may be provided between the APD 201 and the power supply VL to control the avalanche multiplication current. In this case, the voltage divider effect caused by the series resistance can be enhanced. Further, while the sensor configuration in which the sensor substrate 11 and the circuit substrate 21 are stacked according to the present exemplary embodiment is described above, the photoelectric conversion element may be composed solely of the sensor substrate 11 by providing circuits such as the signal processing units 103 to the sensor substrate 11.

### SECOND EXEMPLARY EMBODIMENT

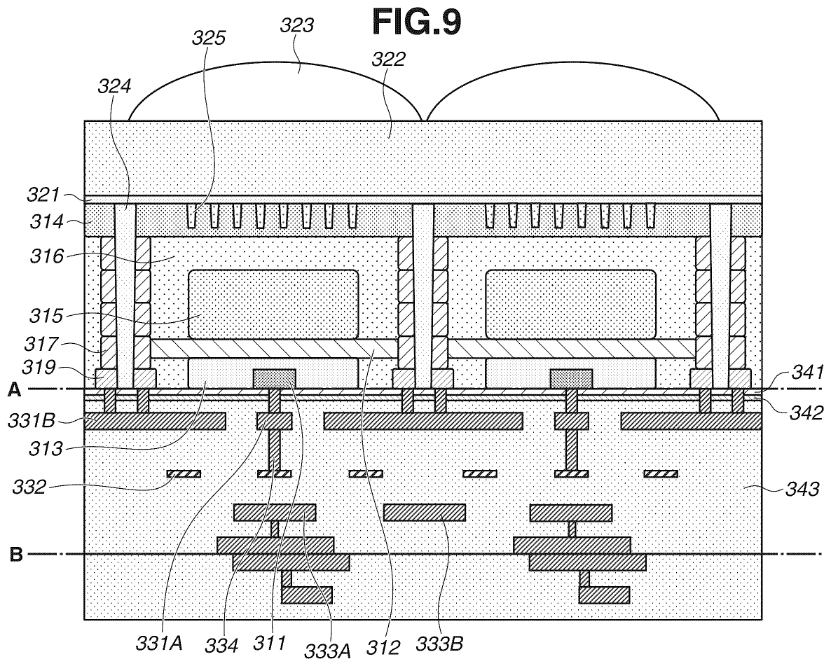

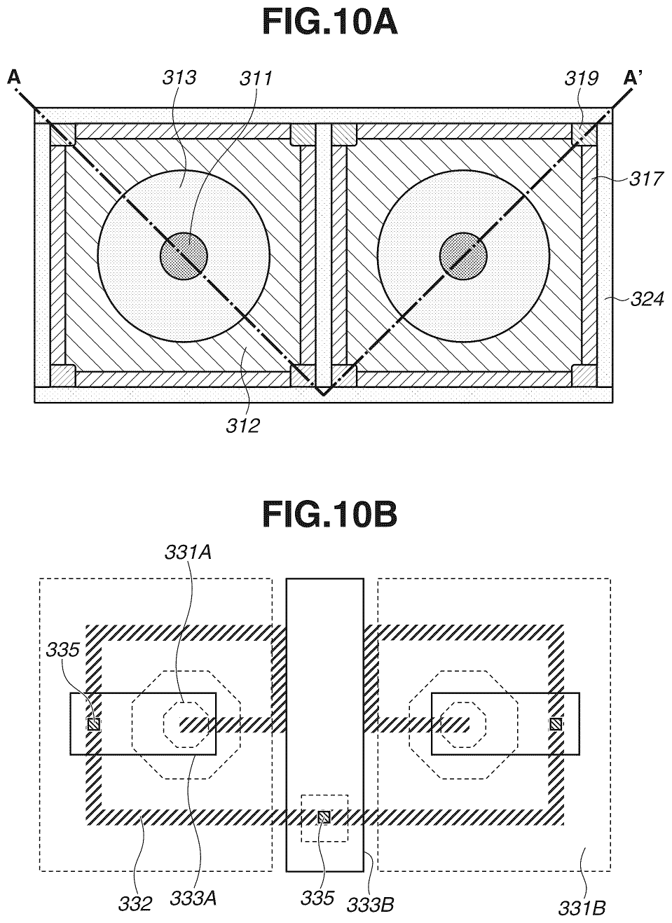

A photoelectric conversion apparatus according to a second exemplary embodiment will be described below with reference to FIGS. 9 and 10B. Descriptions of those that are common to the first exemplary embodiment will be omitted, and mainly the differences from the first exemplary embodiment will be described below. According to the present exemplary embodiment, the resistive elements 332 are formed closer to the circuit substrate 21 than the cathode trace 331A and the anode trace 331B are. With the layout relationship where the wiring portion is formed between the sensor substrate 11 and the resistive element 332, the wiring portion electrostatically shields the effects of changes in the potential of the resistive element 332, which suppresses the influence on the APDs formed on the sensor substrate 11. This suppresses electric field concentration and fluctuations in potential of the APDs in the vicinity of the substrate surface, making it possible to suppress an increase in the DCR.

FIG. 9 is a cross-sectional view illustrating the photoelectric conversion elements 102 of two pixels of the photoelectric conversion apparatus according to the second exemplary embodiment, along the direction perpendicular to the substrate surface direction. The cross-sectional view corresponds to a cross section along A-A′ specified in FIG. 10A. According to the present exemplary embodiment, the wiring portion 333A is not directly connected to the portion where the cathode trace 331A and the resistive element 332 are connected to each other. Specifically, the resistive element 332 and the wiring portion 333A overlap in a plan view, whereas a trace connecting the resistive element 332 and the wiring portion 333A to each other does not overlap with the resistive element 332 or the wiring portion 333A in a plan view.

FIGS. 10A and 10B are plan views illustrating two pixels of the photoelectric conversion apparatus according to the second exemplary embodiment. FIG. 10A is a plan view illustrating the semiconductor regions as viewed from the surface on the opposite side to the light incident surface, and FIG. 10B is a plan view illustrating the wiring portion as viewed from the surface on the opposite side to the light incident surface.

FIG. 10A is equivalent to FIG. 7A according to the first exemplary embodiment.

In FIG. 10B, the resistive element 332 is formed by a fine line pattern and is electrically connected to the cathode trace 331A and the power supply trace 333B via contact plugs and wiring layers. The contact plugs 335 are formed above the middle portions of the resistive element 332 and are electrically connected to the wiring portion 333A. The wiring portion 333A is electrically connected to the signal processing unit 103 arranged on the circuit substrate 21 via the connection trace provided for each pixel. According to the present exemplary embodiment, it is preferable for the formation temperature of the resistive element 332 to be lower than the melting points of the materials used in the wiring portion, and it is preferable to use, for example, amorphous silicon, inorganic transparent electrode, metal thin-film material, ceramic material, or organic material.

### THIRD EXEMPLARY EMBODIMENT

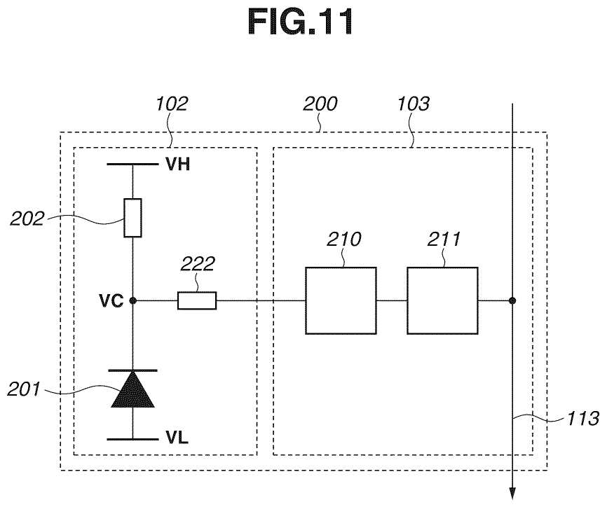

A photoelectric conversion apparatus according to a third exemplary embodiment will be described below with reference to FIG. 11.

Descriptions of those that are common to the first and second exemplary embodiments will be omitted, and mainly the differences from the first exemplary embodiment will be described below. A configuration for reducing a Dead time of the APDs according to the present exemplary embodiment will be described below.

FIG. 11 is an example of a block diagram including an equivalent circuit of a pixel portion of the photoelectric conversion apparatus according to the third exemplary embodiment. According to the present exemplary embodiment, a resistive element 222 is provided between the cathode terminal of the APD 201 and the waveform shaping portion 210. Unlike the first exemplary embodiment, there is no reduction effect on signal amplitude due to resistive voltage division. However, a waveform with a lower amplitude than the signal amplitude of VC is input to the waveform shaping portion 210 due to a low-pass filter effect defined by a resistor of the resistive element 222 and an input capacitor of the waveform shaping portion 210. This facilitates area reduction of the pixel circuit even in cases where Vex is increased, making it possible to achieve both high performance and miniaturization of pixels. Furthermore, since the resistive element 202 is the only resistive element connected in series to the APD 201, Dead time reduction is facilitated.

In FIG. 11, three resistive elements in total may be arranged by adding a resistive element between the APD 201 and a terminal marked as VC.

### FOURTH EXEMPLARY EMBODIMENT

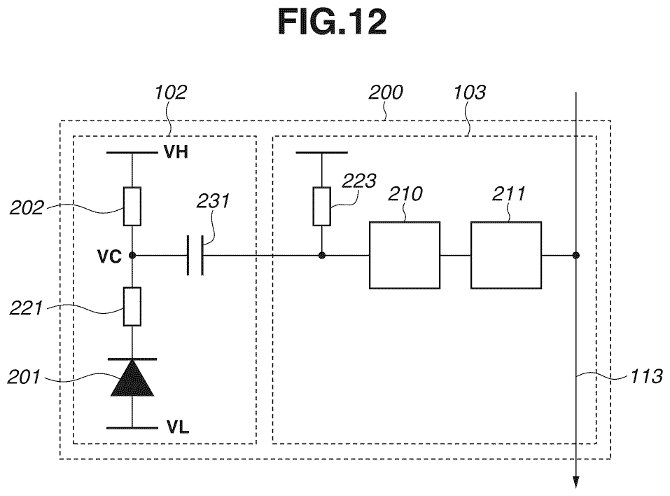

A photoelectric conversion apparatus according to a fourth exemplary embodiment will be described below with reference to FIG. 12.

Descriptions of those that are common to the first, second, and third exemplary embodiments will be omitted, and mainly the differences from the first exemplary embodiment will be described below. A configuration for reducing a Dead time defined by a processing circuit according to the present exemplary embodiment will be described below.

FIG. 12 is an example of a block diagram including an equivalent circuit of a pixel portion of the photoelectric conversion apparatus according to the fourth exemplary embodiment. According to the present exemplary embodiment, a capacitive element 231 and a resistive element 223 are provided between the second resistive element 221 and the waveform shaping portion 210. Unlike the first exemplary embodiment, the capacitive element 231 functions as a high-pass filter, so that a pulse shorter than the signal waveform of VC is input to the waveform shaping portion 210. This makes it possible to reduce an ON period of the pulse input to the subsequent processing circuit including the pixel circuit, facilitating reduction of the Dead time defined by the processing circuit.

A reference potential of an input terminal of the waveform shaping portion 210 may be defined using a transistor instead of the resistive element 223. Further, the capacitive element 231 may be provided between the resistive element 222 according to the third exemplary embodiment and the waveform shaping portion 210 or in front of the resistive element 222.

### FIFTH EXEMPLARY EMBODIMENT

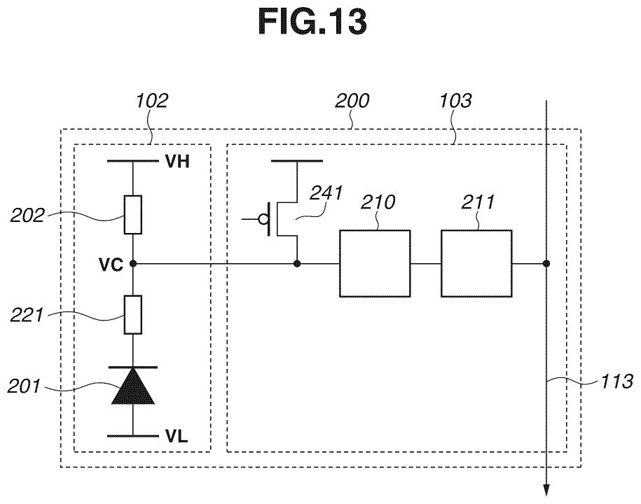

A photoelectric conversion apparatus according to a fifth exemplary embodiment will be described below with reference to FIG. 13.

Descriptions of those that are common to the first, second, third, and fourth exemplary embodiments will be omitted, and mainly the differences from the first exemplary embodiment will be described below. A configuration for reducing signal detection loss by performing a high-speed recharging operation at a desired timing according to the present exemplary embodiment will be described below.

FIG. 13 is an example of a block diagram including an equivalent circuit of a pixel portion of the photoelectric conversion apparatus according to the fifth exemplary embodiment. According to the present exemplary embodiment, a switch element 241 is added to the input terminal of the waveform shaping portion 210. By inputting a control pulse from an external source outside the pixel to a gate terminal of the switch element 241, the potential of VC is returned to VH at a desired timing, and the APD 201 is recharged at high speed. This makes it possible to restore the APD 201 regardless of whether a photon signal is detected at the immediately prior timing, reducing signal detection loss thereby.

An active recharge configuration, in which the output of the circuit following the waveform shaping portion 210 is fed back and input to the gate terminal of the switch element 241, may be employed instead of inputting a control pulse from an external source outside the pixel.

### MODIFIED EXAMPLE OF FIFTH EXEMPLARY EMBODIMENT

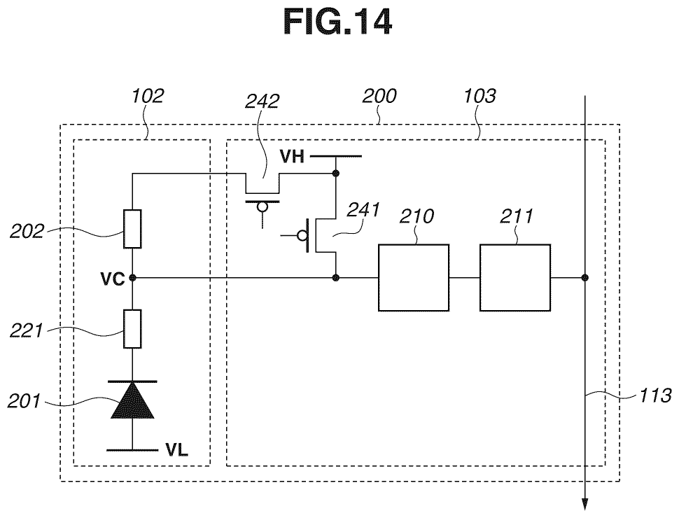

A photoelectric conversion apparatus according to a modified example of the fifth exemplary embodiment will be described below with reference to FIG. 14.

Descriptions of those that are common to the first, second, third, fourth, and fifth exemplary embodiments will be omitted, and mainly the differences from the first exemplary embodiment will be described below. A pixel configuration that allows switching of an operation mode depending on the scene or purpose of use according to the present exemplary embodiment will be described below.

FIG. 14 is an example of a block diagram including an equivalent circuit of a pixel portion of the photoelectric conversion apparatus according to the modified example of the fifth exemplary embodiment. According to the present exemplary embodiment, a switch element 242 is provided between the first resistive element 202 and the power supply VH. By inputting an H level to the gate terminal of the switch element 241 to turn off the switch and inputting an L level to a gate terminal of the switch element 242 to turn

ON the switch, a circuit configuration similar to the first exemplary embodiment is obtained. Further, by inputting the H level to the gate terminal of the switch element 242 to turn OFF the switch and inputting the L level to the gate terminal of the switch element 241 to turn ON the switch, it becomes possible to select a resistive voltage division ratio different from the above-described drive, enabling adjustment of the signal amplitude and Dead time thereby. Further, by inputting the H level to the gate terminal of the switch element 242 to turn OFF the switch and inputting a periodic pulse signal to a gate of the switch element 241, a clock recharge drive is realized, enabling operation at lower power consumption.

As described above, the present exemplary embodiment makes it possible to reduce the Dead time depending on the scene or purpose of use and reduce the power consumption.

### SIXTH EXEMPLARY EMBODIMENT

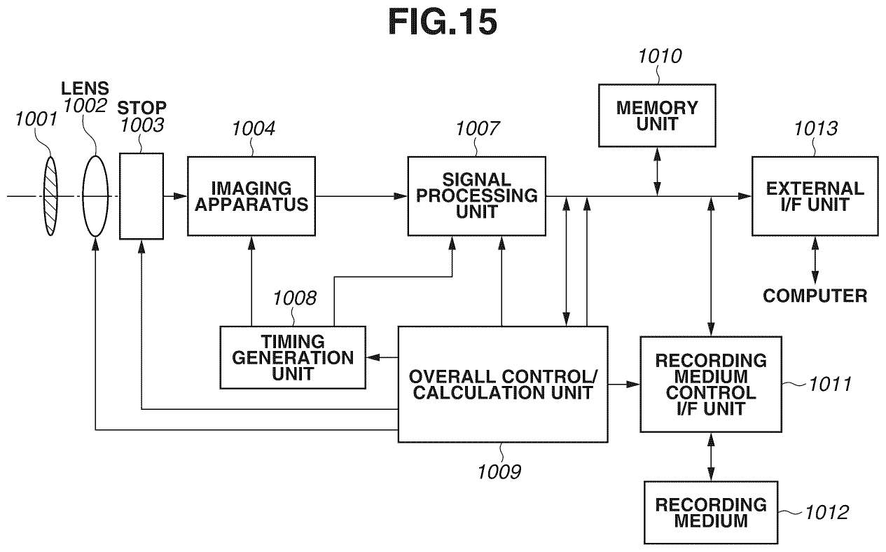

A photoelectric conversion system according to the present exemplary embodiment will be described below with reference to FIG. 15. FIG. 15 is a block diagram illustrating a schematic configuration of the photoelectric conversion system according to the present exemplary embodiment.

The photoelectric conversion apparatuses according to the first to sixth exemplary embodiments are applicable to various photoelectric conversion systems. Examples of applicable photoelectric conversion systems include digital still cameras, digital camcorders, surveillance camera, copy machines, fax machines, mobile phones, on-vehicle cameras, and observation satellites. Further, camera modules including an optical system such as a lens and an imaging apparatus are also included in the photoelectric conversion systems. In FIG. 15, an example of a block diagram illustrating a digital still camera as one of the examples is illustrated.

The photoelectric conversion system illustrated as an example in FIG. 15 includes an imaging apparatus 1004 and a lens 1002. The imaging apparatus 1004 is an example of the photoelectric conversion apparatus, and the lens 1002 forms an optical image of a subject on the imaging apparatus 1004. A stop 1003 for varying the amount of light passing through the lens 1002 and a barrier 1001 for protecting the lens 1002 are further included. The lens 1002 and the stop 1003 are an optical system that focuses light onto the imaging apparatus 1004. The imaging apparatus 1004 is the photoelectric conversion apparatus according to any one of the exemplary embodiments and converts an optical image formed by the lens 1002 into an electric signal.

The photoelectric conversion system further includes a signal processing unit 1007. The signal processing unit 1007 is an image generation unit that generates images by processing output signals output from the imaging apparatus 1004. The signal processing unit 1007 performs an operation of performing various types of correction and/or compression when necessary and outputting image data. The signal processing unit 1007 may be formed on the semiconductor substrate on which the imaging apparatus 1004 is provided, or on another semiconductor substrate separately from the imaging apparatus 1004.

The photoelectric conversion system further includes a memory unit 1010 for temporarily storing image data and an external interface unit (external I/F unit) 1013 for communicating with external computers. The photoelectric conversion system further includes a recording medium 1012 such as a semiconductor memory for recording or reading captured data and a recording medium control interface unit (recording medium control I/F unit) 1011 for performing recording or reading on the recording medium 1012. The recording medium 1012 may be built in the photoelectric conversion system or may be removable.

The photoelectric conversion system further includes an overall control/calculation unit 1009 and a timing generation unit 1008. The overall control/calculation unit 1009 controls various calculations and the entire digital still camera, and the timing generation unit 1008 outputs various timing signals to the imaging apparatus 1004 and the signal processing unit 1007. The timing signals may be input from an external source, and the photoelectric conversion system is to include at least the imaging apparatus 1004 and the signal processing unit 1007, which processes output signals output from the imaging apparatus 1004.

The imaging apparatus 1004 outputs an imaging signal to the signal processing unit 1007. The signal processing unit 1007 performs predetermined signal processing on the imaging signal output from the imaging apparatus 1004 and outputs image data. The signal processing unit 1007 generates an image using the imaging signal.

As described above, the present exemplary embodiment makes it possible to realize a photoelectric conversion system to which the photoelectric conversion apparatus (imaging apparatus) according to any one of the exemplary embodiments is applied.

### SEVENTH EXEMPLARY EMBODIMENT

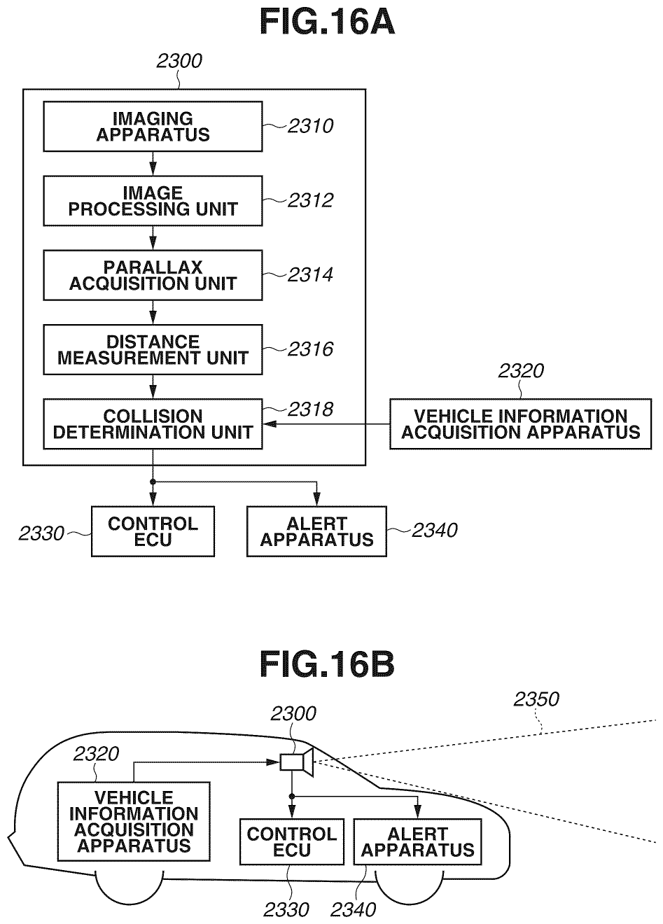

A photoelectric conversion system and a moving object according to the present exemplary embodiment will be described below with reference to FIGS. 16A and 16B. FIGS. 16A and 16B are diagrams illustrating configurations of a photoelectric conversion system and a moving object according to the present exemplary embodiment.

FIG. 16A illustrates an example of a photoelectric conversion system related to an on-vehicle camera. A photoelectric conversion system 2300 includes an imaging apparatus 2310. The imaging apparatus 2310 is the photoelectric conversion apparatus according to any one of the exemplary embodiments. The photoelectric conversion system 2300 includes an image processing unit 2312 and a parallax acquisition unit 2314.

The image processing unit 2312 performs image processing on a plurality of pieces of image data acquired by the imaging apparatus 2310, and the parallax acquisition unit 2314 calculates parallax (phase difference between parallax images) from the plurality of pieces of image data acquired by the photoelectric conversion system 2300. Further, the photoelectric conversion system 2300 includes a distance acquisition unit 2316 and a collision determination unit 2318. The distance acquisition unit 2316 calculates a distance to a target object based on the calculated parallax, and the collision determination unit 2318 determines whether there is a possibility of a collision based on the calculated distance. The parallax acquisition unit 2314 and the distance acquisition unit 2316 are an example of a distance information acquisition unit that acquires distance information to the target object. Specifically, the distance information is information regarding parallax, defocus amount, and distance to the target object. The collision determination unit 2318 can determine the possibility of a collision using any of the distance information. The distance information acquisition unit can be realized by dedicated hardware or a software module.

It is also possible to realize using a Field Programmable Gate Array (FPGA), an Application Specific Integrated Circuit (ASIC), or a combination thereof.

The photoelectric conversion system 2300 is connected to a vehicle information acquisition apparatus 2320 and is capable of acquiring vehicle information such as vehicle speed, yaw rate, and steering angle. Further, a control electronic control unit (control ECU) 2330 is connected to the photoelectric conversion system 2300. The control ECU 2330 is a control unit that outputs a control signal for generating braking force for the vehicle based on the determination result of the collision determination unit 2318. Further, an alert apparatus 2340 is also connected to the photoelectric conversion system 2300. The alert apparatus 2340 issues an alert to a driver based on the determination result of the collision determination unit 2318. For example, in a case where the collision determination unit 2318 determines that there is a high possibility of a collision, the control ECU 2330 performs vehicle control to avoid a collision or mitigate damage by applying brakes, releasing an accelerator, and/or suppressing engine output. The alert apparatus 2340 alerts the user by sounding an alert such as an audible alert, displaying alert information on a screen of a car navigation system, and/or applying vibrations to a seatbelt and steering wheel.

According to the present exemplary embodiment, the photoelectric conversion system 2300 captures images of the surroundings of the vehicle, such as the front or rear of the vehicle. FIG. 16B illustrates a photoelectric conversion system configured to capture images of the front of the vehicle (imaging range 2350). The vehicle information acquisition apparatus 2320 transmits instructions to the photoelectric conversion system 2300 or the imaging apparatus 2310. This configuration makes it possible to further improve distance measurement accuracy.

While an example in which control is performed to avoid collisions with other vehicles is described above, it can also be applied to control for automated driving that follows other vehicles or control for automated driving to prevent straying from lanes. Furthermore, the photoelectric conversion system is applicable to not only vehicles such as own vehicles but also moving objects (moving apparatuses) such as vessels, aircraft, or industrial robots. Furthermore, it can also be applied to not only moving objects but also equipment that widely uses object recognition, such as intelligent transportation systems (ITS).

### EIGHTH EXEMPLARY EMBODIMENT

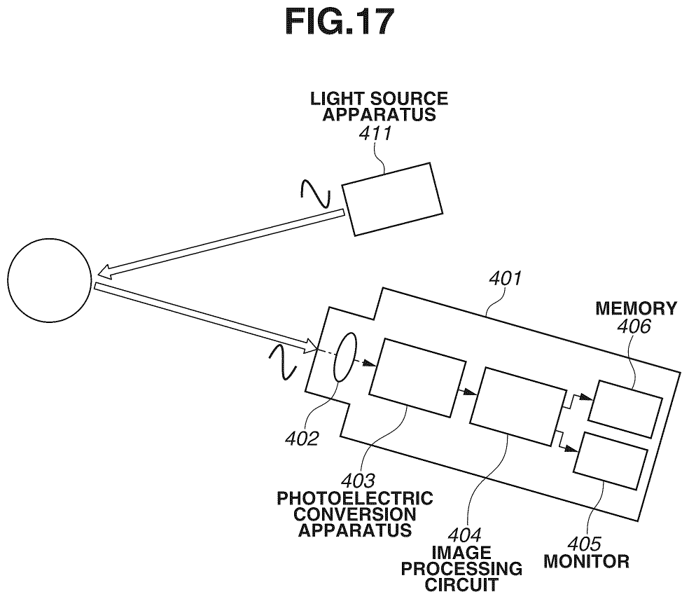

A photoelectric conversion system according to the present exemplary embodiment will be described below with reference to FIG. 17. FIG. 17 is a block diagram illustrating an example of a configuration of a distance image sensor that is the photoelectric conversion system according to the present exemplary embodiment.

As illustrated in FIG. 17, a distance image sensor 401 includes an optical system 402, a photoelectric conversion apparatus 403, an image processing circuit 404, a monitor 405, and a memory 406. Further, the distance image sensor 401 acquires a distance image corresponding to a distance to a subject by receiving light (modulated light or pulse light) emitted from a light source apparatus 411 to the subject and reflected from a surface of the subject.

The optical system 402 includes one or more lenses and guides image light (incident light) from the subject to the photoelectric conversion apparatus 403 to form an image on a light receiving surface (sensor portion) of the photoelectric conversion apparatus 403.

The photoelectric conversion apparatus according to one of the exemplary embodiments is applied to the photoelectric conversion apparatus 403, and a distance signal indicating a distance obtained from a received light signal output from the photoelectric conversion apparatus 403 is supplied to the image processing circuit 404.

The image processing circuit 404 performs image processing to generate a distance image based on the distance signal supplied from the photoelectric conversion apparatus 403. Then, the distance image (image data) obtained through the image processing is supplied to the monitor 405 and displayed and/or supplied to the memory 406 and stored (recorded).

By applying the photoelectric conversion apparatus described above to the distance image sensor 401 configured as described above, pixel characteristics improve, which makes it possible to, for example, acquire more accurate distance images.

### NINTH EXEMPLARY EMBODIMENT

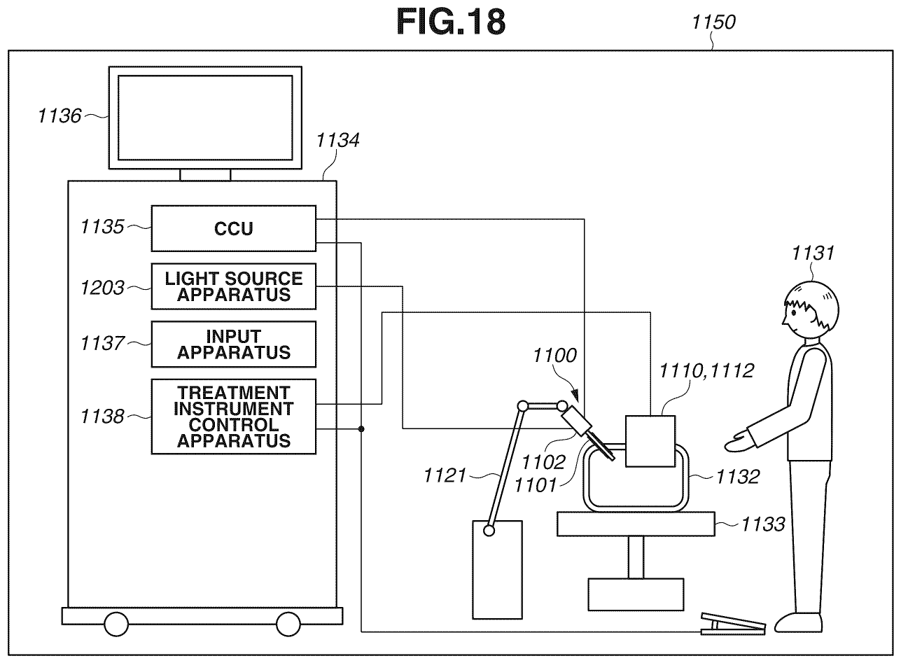

A photoelectric conversion system according to the present exemplary embodiment will be described below with reference to FIG. 18. FIG. 18 is a diagram illustrating an example of a schematic configuration of an endoscopic surgery system, which is a photoelectric conversion system according to the present exemplary embodiment.

In FIG. 18, an operator (doctor) 1131 performing an operation on a patient 1132 on a patient bed 1133 using an endoscopic surgery system 1150 is illustrated. As illustrated, the endoscopic surgery system 1150 includes an endoscope 1100, an instrument 1110, and a cart 1134 in which various apparatuses for the endoscopic surgery are installed.

The endoscope 1100 includes a tube 1101 and a camera head 1102 connected to a base end of the tube 1101. A region of a predetermined length from a tip of the tube 1101 is inserted into the body cavity of the patient 1132. In the illustrated example, the endoscope 1100 configured as a rigid endoscope including the rigid tube 1101 is illustrated. However, the endoscope 1100 may be configured as a flexible endoscope including a flexible tube.

The tip of the tube 1101 includes an opening portion into which an objective lens is fitted. A light source apparatus 1203 is connected to the endoscope 1100, and light generated by the light source apparatus 1203 is guided to the tip of the tube by a light guide extending in the tube 1101 and illuminates an observation target in the body cavity of the patient 1132 through the objective lens. The endoscope 1100 may be a forward-view endoscope, an angled endoscope, or a side-viewing endoscope.

An optical system and a photoelectric conversion apparatus are provided inside the camera head 1102, and reflected light (observation light) from the observation target is focused onto the photoelectric conversion apparatus by the optical system. The photoelectric conversion apparatus photoelectrically convers the observation light, and an electric signal corresponding to the observation light, i.e., an image signal corresponding to an observational image, is generated. The photoelectric conversion apparatus according to any of the exemplary embodiments can be used as the photoelectric conversion apparatus. The image signal is transmitted as RAW data to a camera control unit (CCU) 1135.

The CCU 1135 includes a central processing unit (CPU) and a graphics processing unit (GPU) and comprehensively controls operations of the endoscope 1100 and a display apparatus 1136. Further, the CCU 1135 receives an image signal from the camera head 1102 and performs various types of image processing, such as development processing (demosaic processing), on the image signal to display an image based on the image signal.

The display apparatus 1136 is controlled by the CCU 1135 to display an image based on the image signal that has undergone the image processing performed by the CCU 1135.

The light source apparatus 1203 is composed of a light source such as a light emitting diode (LED) and supplies the endoscope 1100 with illumination light during imaging of a surgical field.

An input apparatus 1137 is an input interface for an endoscopic surgery system 1150. The user can input various types of information and instructions to the endoscopic surgery system 1150 via the input apparatus 1137.

A treatment instrument control apparatus 1138 controls driving of an energy treatment instrument 1112 for tissue coagulation, incision, or vessel sealing.

The light source apparatus 1203, which supplies the endoscope 1100 with illumination light during imaging of the surgical field, can be composed of a white light source composed of, for example, an LED, a laser light source, or a combination thereof. In cases where the white light source is composed of a combination of RGB laser light sources, it is possible to control an output intensity and output timing of each color (each wavelength) with high accuracy, which makes it possible for the light source apparatus 1203 to perform white balance adjustment of captured images. Further, in this case, images corresponding to RGB can be captured using time-division techniques by illuminating the observation target with laser light from each of the RGB laser light sources using time-division techniques and controlling driving of an image sensor of the camera head 1102 in synchronization with the illumination timing. With this method, color images can be obtained without providing color filters to the image sensor.

Further, driving of the light source apparatus 1203 may be controlled to vary the output light intensity at each predetermined time. By controlling the driving of the image sensor of the camera head 1102 in synchronization with the timing of changing the light intensity to acquire images using time-division techniques and combining the acquired images together, it becomes possible to generate a high dynamic range image without black clipping and white clipping.

Further, the light source apparatus 1203 may be configured to supply light within a predetermined wavelength band suitable for special light observation. The special light observation utilizes, for example, the wavelength dependence of light absorption in body tissue. Specifically, when predetermined tissue such as blood vessels in the superficial mucosal layer is illuminated with light within a narrower band than the illumination light (i.e., white light) used in normal observation, images with high contrast are captured. Further, in special light observation, fluorescence observation may be performed to obtain images using fluorescence generated by illuminating with excitation light. In fluorescence observation, the body tissue is illuminated with excitation light to observe fluorescence from the body tissue, or a reagent such as indocyanine green (ICG) is administered locally to the body tissue and the body tissue is illuminated with excitation light corresponding to fluorescent wavelengths of the reagent to obtain fluorescent images. The light source apparatus 1203 may be configured to supply light within a narrower band and/or excitation light suitable for the special light observation.

### TENTH EXEMPLARY EMBODIMENT

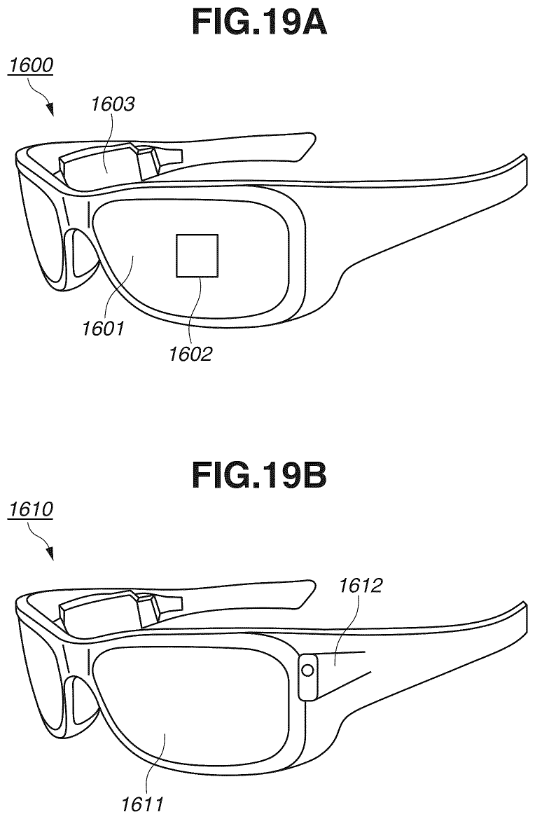

A photoelectric conversion system according to the present exemplary embodiment will be described below with reference to FIGS. 19A and 19B. FIG. 19A illustrates glasses 1600 (smart glasses), which is the photoelectric conversion system according to the present exemplary embodiment. The glasses 1600 include a photoelectric conversion apparatus 1602. The photoelectric conversion apparatus 1602 is the photoelectric conversion apparatus according to any of the exemplary embodiments. Further, a display apparatus including a light emitting apparatus, such as an organic LED (OLED) or LED, may be provided on the rear side of a lens 1601. One or more photoelectric conversion apparatuses 1602 may be provided. Further, a plurality of types of photoelectric conversion apparatuses may be used in combination. The layout position of the photoelectric conversion apparatus 1602 is not limited to that in FIG. 19A.

The glasses 1600 further include a control apparatus 1603. The control apparatus 1603 functions as a power supply that supplies power to the photoelectric conversion apparatus 1602 and the display apparatus. Further, the control apparatus 1603 controls operations of the photoelectric conversion apparatus 1602 and the display apparatus. An optical system for focusing light onto the photoelectric conversion apparatus 1602 is formed on the lens 1601.

FIG. 19B illustrates glasses 1610 (smart glasses) according to an application example. The glasses 1610 include a control apparatus 1612, and a photoelectric conversion apparatus corresponding to the photoelectric conversion apparatus 1602 and a display apparatus are mounted on the control apparatus 1612. The photoelectric conversion apparatus in the control apparatus 1612 and an optical system for projecting light emitted from the display apparatus are formed on a lens 1611, and images are projected onto the lens 1611. The control apparatus 1612 functions as a power supply that supplies power to the photoelectric conversion apparatus and the display apparatus, and controls operations of the photoelectric conversion apparatus and the display apparatus. The control apparatus 1612 may include a gaze detection unit configured to detect the gaze of a wearer. Infrared rays may be used in gaze detection. An infrared light emitting portion emits infrared light toward eyeballs of the user gazing at a displayed image. The emitted infrared light reflected from the eyeballs is detected by an imaging unit including a light receiving element, whereby captured images of the eyeballs are obtained. By including a reduction unit configured to reduce light from the infrared light emitting portion to a display unit in a plan view, the degradation of image quality is reduced.

The gaze of the user at the display image is detected from the captured eyeball images obtained through infrared imaging. Any publicly known method is applicable to the gaze detection using the captured eyeball images. For example, a gaze detection method based on Purkinje images from reflections of illumination light on the cornea can be used.

More specifically, a gaze detection process based on a pupil-corneal reflection method is performed. The gaze of the user is detected by calculating gaze vectors representing eyeball directions (rotation angles) based on pupil images and Purkinje images included in the captured eyeball images using the pupil-corneal reflection method.

The display apparatus according to the present exemplary embodiment includes a photoelectric conversion apparatus including a light receiving element, and a displayed image on the display apparatus may be controlled based on user gaze information from the photoelectric conversion apparatus.

Specifically, a first field-of-view region at which the user gazes and a second field-of-view region other than the first field-of-view region are determined for the display apparatus based on gaze information. The first field-of-view region and the second field-of-view region may be determined by a control apparatus of the display apparatus, or the display apparatus may receive the first field-of-view region and the second field-of-view region that are determined by an external control apparatus. In a display region of the display apparatus, the first field-of-view region may be controlled to have a higher display resolution than the second field-of-view region. Specifically, the resolution of the second field-of-view region may be set lower than the resolution of the first field-of-view region.

Further, the display region includes a first display region and a second display region different from the first display region, and a high-priority region may be determined from the first display region and the second display region based on the gaze information. The first display region and the second display region may be determined by the control apparatus of the display apparatus, or the display apparatus may receive the first display region and the second display region that are determined by an external control apparatus. The high-priority region may be controlled to have a higher resolution than that of the region other than the high-priority region. In other words, the resolution of the relatively low-priority region may be set low.

Artificial Intelligence (AI) may be used in determining the first display region or the high-priority region. AI may be a model designed to estimate the gaze angle and distance to a target object at the end of the gaze based on the eyeball images using, as training data, the eyeball images and the directions in which the eyeballs in the eyeball images were actually directed. AI programs may be included in the display apparatus, the photoelectric conversion apparatus, or an external apparatus. In cases where an external apparatus includes the Al programs, the AI programs are transmitted to the display apparatus through communication.

Display control based on visual recognition detection is applicable to smart glasses further including a photoelectric conversion apparatus configured to capture external images. The smart glasses are capable of displaying captured external information in real time.

### MODIFIED EXEMPLARY EMBODIMENTS

The present invention is not limited to the exemplary embodiments, and various modifications can be made.

For example, an example in which a portion of a configuration of one of the exemplary embodiments is added to another exemplary embodiment and an example in which a portion of a configuration of one of the exemplary embodiments is replaced with a portion of a configuration of another exemplary embodiment are also included in the exemplary embodiments of the present invention.

Further, the photoelectric conversion systems according to the sixth and seventh exemplary embodiments merely illustrate examples of photoelectric conversion systems to which the photoelectric conversion apparatuses are applicable, and the photoelectric conversion systems to which the photoelectric conversion apparatuses of the present invention are applicable are not limited to the configurations illustrated in FIGS. 15 to 16B. The same applies to the ToF systems according to the eighth exemplary embodiment, the endoscopes according to the ninth exemplary embodiment, and the smart glasses according to the tenth exemplary embodiment.

The photoelectric conversion apparatuses according to the exemplary embodiments are also applicable to in-vehicle sensors. Examples include sensors for detecting a face of a driver, facial expressions, or gaze. A lack of attention, drowsiness, or fainting of the driver can be detected using the output of the sensors. Further, driver identification can also be performed.

It should be noted that the exemplary embodiments merely illustrate concrete examples for implementing the present invention and the technical scope of the present invention should not be interpreted narrowly by the exemplary embodiments. Specifically, the present invention can be implemented in various forms without departing from the technical concept or major features of the present invention.

The present invention makes it possible to achieve both high performance and miniaturization of pixels.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A photoelectric conversion apparatus including:
a first substrate including a first semiconductor layer and a first wiring structure stacked on the first semiconductor layer; and
a second substrate including a second semiconductor layer and a second wiring structure stacked on the second semiconductor layer, the photoelectric conversion apparatus comprising:
an avalanche photodiode arranged on the first semiconductor layer;
a first resistive element arranged on the first substrate and connected to the avalanche photodiode;
a waveform shaping portion arranged on the second semiconductor layer and configured to shape an output signal of the avalanche photodiode; and
a second resistive element arranged on the first substrate and connected to the avalanche photodiode, the waveform shaping portion, and the first resistive element,
wherein three or more contact plugs are connected to the first resistive element and the second resistive element.

2. The photoelectric conversion apparatus according to claim 1, wherein the second resistive element is connected between the avalanche photodiode and the first resistive element.

3. The photoelectric conversion apparatus according to claim 1, wherein the second resistive element is connected between the first resistive element and the waveform shaping portion.

4. The photoelectric conversion apparatus according to claim 1,
wherein a plurality of the avalanche photodiodes is included, and
wherein the first resistive element connected to a first avalanche photodiode of the plurality of avalanche photodiodes and the first resistive element connected to a second avalanche photodiode of the plurality of avalanche photodiodes are arranged on a same plane parallel to a surface of the first semiconductor layer.

5. The photoelectric conversion apparatus according to claim 1, wherein at least one of the first resistive element and the second resistive element contains polysilicon or amorphous silicon.

6. The photoelectric conversion apparatus according to claim 1, wherein at least one of the first resistive element and the second resistive element contains metal thin-film material.

7. The photoelectric conversion apparatus according to claim 1, wherein at least one of the first resistive element and the second resistive element contains ceramic material.

8. The photoelectric conversion apparatus according to claim 1, wherein at least one of the first resistive element and the second resistive element contains organic material.

9. The photoelectric conversion apparatus according to claim 1, wherein a ratio of a shortest side to a longest side of at least one of the first resistive element and the second resistive element is 10 or higher.

10. The photoelectric conversion apparatus according to claim 1, wherein at least one of the first resistive element and the second resistive element contains a material with higher resistivity than a main material of a trace.

11. The photoelectric conversion apparatus according to claim 1, wherein at least one of the first resistive element and the second resistive element contains a material with higher resistivity than a main material of a via that supplies voltage to the avalanche photodiode.

12. The photoelectric conversion apparatus according to claim 1, wherein at least one of the first resistive element and the second resistive element overlaps with a cathode of the avalanche photodiode in a plan view.

13. The photoelectric conversion apparatus according to claim 1, wherein a resistive element is connected to both a cathode and an anode of the avalanche photodiode.

14. The photoelectric conversion apparatus according to claim 1, wherein the waveform shaping portion and at least one of the first resistive element and the second resistive element are connected via a capacitive element.

15. The photoelectric conversion apparatus according to claim 2, wherein at least one of the first resistive element and the second resistive element extends along a direction in which the first semiconductor layer and the second semiconductor layer are stacked.

16. The photoelectric conversion apparatus according to claim 1, wherein two power supply wiring systems for supplying voltage to a cathode and an anode of the avalanche photodiode are arranged on the first substrate.

17. The photoelectric conversion apparatus according to claim 1, wherein a resistance value of the second resistive element is greater than or equal to a resistance value of the first resistive element.

18. The photoelectric conversion apparatus according to claim 1, wherein the first resistive element and the second resistive element are arranged on the same plane parallel to a surface of the first semiconductor layer.

19. The photoelectric conversion apparatus according to claim 18, wherein a contact plug is connected to both an upper side and a lower side of the first resistive element and the second resistive element.

20. The photoelectric conversion apparatus according to claim 1, further comprising a switch connected between an input terminal of the waveform shaping portion and a trace that supplies a reference voltage.

21. The photoelectric conversion apparatus according to claim 1, further comprising a switch connected between a terminal of the first resistive element that is not connected to the waveform shaping portion and a trace that supplies a reference voltage.

22. A photoelectric conversion apparatus including:
a first substrate including a first semiconductor layer and a first wiring structure stacked on the first semiconductor layer; and
a second substrate including a second semiconductor layer and a second wiring structure stacked on the second semiconductor layer, the photoelectric conversion apparatus comprising:
an avalanche photodiode arranged on the first semiconductor layer;
a first resistive element arranged on the first substrate and connected to the avalanche photodiode;
a waveform shaping portion arranged on the second semiconductor layer and configured to shape an output signal of the avalanche photodiode; and
a second resistive element arranged on the first substrate and connected to the avalanche photodiode, the waveform shaping portion, and the first resistive element; and
a switch connected between a terminal of the first resistive element that is not connected to the waveform shaping portion and a trace that supplies a reference voltage.

23. The photoelectric conversion apparatus according to claim 22, wherein a periodic pulse signal is input to a gate of the switch.

24. A photoelectric conversion system comprising:
the photoelectric conversion apparatus according to claim 1; and
a signal processing unit configured to generate an image using a signal output from the photoelectric conversion apparatus.

25. A moving object comprising the photoelectric conversion apparatus according to claim 1, the moving object further comprising a control unit configured to control movement of the moving object using a signal output from the photoelectric conversion apparatus.

26. A photoelectric conversion system comprising:
the photoelectric conversion apparatus according to claim 1; and
a signal processing unit configured to generate an image using a signal output from the photoelectric conversion apparatus.

27. A moving object comprising the photoelectric conversion apparatus according to claim 1, the moving object further comprising a control unit configured to control movement of the moving object using a signal output from the photoelectric conversion apparatus.
